(19) United States
(12) Patent Application Publication
(10) Pub. No.: US 2010/0254084 A1
(43) Pub. Date: Oct. 7, 2010

(54) MOTHERBOARD INTEGRATED WITH FAN

(76) Inventors: Kuan-Ying Chen, TAIPEI CITY (TW); Chao-Tsai Chung, TAIPEI CITY (TW)

Correspondence Address: NORTH AMERICA INTELLECTUAL PROPERTY CORPORATION, P.O. BOX 506, MERRIFIELD, VA, 22116, US

(21) Appl. No.: 12/731,156

(22) Filed: Mar. 25, 2010

(30) Foreign Application Priority Data
Apr. 2, 2009 (TW) 098111078

(51) Int. Cl. H05K 7/20

(52) U.S. Cl. 361/695

(57) ABSTRACT

A motherboard integrated with a fan includes a circuit board, a stator, and a blade assembly. The circuit board has at least one hole. The stator is disposed at the circuit board. The blade assembly is rotatably mounted to the stator. When the stator drives the blade assembly to rotate, airflow is formed and passes through the hole.

### CROSS-REFERENCE TO RELATED APPLICATIONS

This Non-provisional application claims priority under 35 U.S.C.§119(a) on Patent Application No(s). 098111078 filed in Taiwan, Republic of China on Apr. 2, 2009, the entire contents of which are hereby incorporated by reference.

### BACKGROUND OF THE INVENTION

1. Field of the Invention

This invention relates to a motherboard and, more particularly, to a motherboard integrated with a fan.

2. Description of the Related Art

In recent years, operating speed of a computer continuously increases, and heat generating from electronic elements in a computer casing also continuously increases. A notebook computer is taken for example. Since a chip of the notebook computer has a high calculation speed, the chip may generate a large number of heat. The heat generated by the chip, such as a central processing unit (CPU), has to be effectively dissipated to allow the chip to be in a normal working state. In the prior art, a heat pipe is usually disposed on the chip. Thus, the heat pipe can transfer the heat generated from the chip to a heat dissipating fin by the high heat conducting characteristics of heat pipe. Active airflow generated by a fan will take out the heat of the heat dissipating fin, thereby cooling the chip.

Since the notebook computer at the market has light and thin features, a fan is not easy to be assembled in the limited interior space of the notebook computer.

### BRIEF SUMMARY OF THE INVENTION

This invention provides a motherboard integrated with a fan to reduce volume of the fan and to reduce integral height.

The invention provides a motherboard integrated with a fan. In one embodiment, the motherboard includes a circuit board, a stator, and a blade assembly. The circuit board has at least one hole. The stator is disposed at the circuit board. The blade assembly is rotatably mounted to the stator. When the stator drives the blade assembly to rotate, airflow is formed and passes through the hole.

In one embodiment of the invention, the motherboard may further include a fan control unit disposed at the circuit board and electrically connected with the stator. In addition, the fan control unit may include a diode and a resistor. The circuit board may include a circuit electrically connected with the stator and the fan control unit.

In one embodiment of the invention, the motherboard may further include a bearing. The stator includes a plurality of stator coils disposed around the bearing. In addition, the motherboard may further include a shaft sleeved in the bearing. The blade assembly may include a hub casing, a plurality of blades, and a plurality of magnets. The hub casing covers the stator and is assembled at the shaft. The blades are connected to the outside of the hub casing. The magnets are disposed in the hub casing and correspond to the stator coils. In addition, the motherboard may include a Hall element and a fan control unit. The fan control unit is disposed at the circuit board and is electrically connected with the stator. The Hall element is disposed at the circuit board and is electrically connected with the fan control unit via the circuit board to transmit a voltage corresponding to a rotating speed of the blade assembly to the fan control unit.

In one embodiment of the invention, the circuit board may include at least one connecting portion adjacent to the hole.

In one embodiment of the invention, the blade assembly is a centrifugal blade assembly.

In one embodiment of the invention, the motherboard may further include a guiding casing fastened to the circuit board and covering the blade assembly. The guiding casing may have a plurality of fastening elements fastened to the circuit board. The fastening elements may also be fastened to a casing to fasten the guiding casing to a certain position corresponding to the blade assembly during assembling. In addition, the guiding casing may have an air inlet corresponding to the blade assembly.

In one embodiment of the invention, the motherboard may have a central processing unit connector, a chipset, and a memory module connector. The central processing unit connector, the chipset, and the memory module connector are disposed at the circuit board, and the central processing unit connector and the memory module connector are electrically connected with the chipset. In addition, the motherboard may include at least one input/output device electrically connected with the chipset.

According to the embodiment of the invention, components of a fan are integrated to the circuit board, and the hole of the circuit board is used as an air inlet. Thus, the volume of the fan can be reduced, the height of the motherboard can be reduced, and component cost can also be saved.

These and other features, aspects, and advantages of the present invention will become better understood with regard to the following description, appended claims, and accompanying drawings.

### BRIEF DESCRIPTION OF THE DRAWINGS

FIG. 1 is a partial schematic diagram showing a motherboard according to one embodiment of the invention;

FIG. 2 is a sectional schematic diagram showing a blade assembly, a stator, and a part of the motherboard in FIG. 1;

FIG. 3 is a partial schematic diagram showing a motherboard according to another embodiment of the invention;

FIG. 4 is a sectional schematic diagram showing a blade assembly, a stator, and a part of the motherboard according to another embodiment of the invention;

FIG. 5 is a schematic diagram showing a guiding casing according to one embodiment of the invention;

FIG. 6 is a schematic diagram showing the guiding casing in FIG. 5 fastened to the motherboard in FIG. 1;

FIG. 7 is a partial schematic diagram showing a guiding casing fastened to a motherboard according to another embodiment of the invention;

FIG. 8 is a partial schematic diagram showing a motherboard according to a third embodiment of the invention; and

FIG. 9 is a side schematic diagram showing the motherboard in FIG. 8 and a casing assembled at the motherboard.

### DETAILED DESCRIPTION OF THE INVENTION

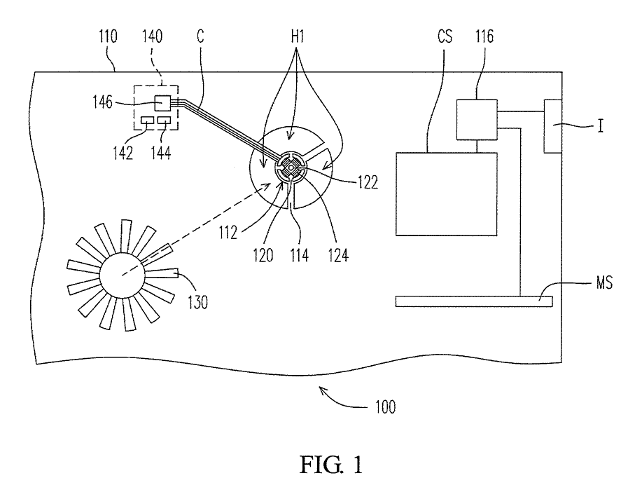

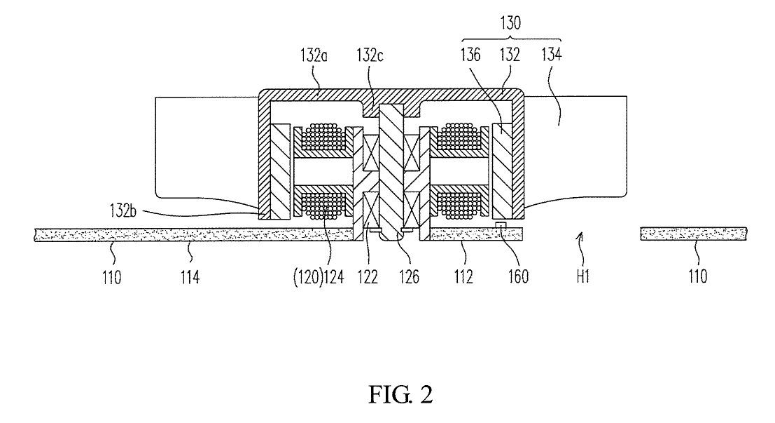

FIG. 1 is partial schematic diagram showing a motherboard according to one embodiment of the invention. FIG. 2 is a sectional schematic diagram showing a blade assembly, a stator, and a part of the motherboard in FIG. 1. Please refer to FIG. 1 and FIG. 2. A motherboard 100 integrated with a fan includes a circuit board 110, a stator 120, and a blade assembly 130. The circuit board 110 has at least one hole H1 and a supporting area 112. In the embodiment, the supporting area 112 is surrounded by the three holes H1. The circuit board 110 further have three connecting portions 114 connected between the supporting area 112 and the circuit board 110 at the outside of the holes H1.

In the embodiment, the stator 120 is disposed at the supporting area 112 and includes a plurality of stator coils 124. The motherboard 100 can further include a bearing 122 and a shaft 126. The stator coils 124 are disposed around the bearing 122, and the shaft 126 is sleeved in the bearing 122. The blade assembly 130 include a hub casing 132, a plurality of blades 134, and a plurality of magnets 136. The hub casing 132 is a cylinder and includes a top wall 132a and a side wall 132b. In addition, the hub casing 132 cover the stator 120 and is assembled at the shaft 126. The blades 134 are disposed at the outside of the side wall 132b, and the magnets 136 are disposed at the inner side of the side wall 132b and correspond to the stator coils 124.

The position of the blade assembly 130 in FIG. 1 is not the actual assembled position at the circuit board 110. In FIG. 1, to clearly show the stator 120, the blade assembly 130 is shown in the other position. In an actual status, the blade assembly 130 is mounted to the stator 120.

In the embodiment, the blade assembly 130 have a sleeved portion 132c located at the inner side of the top wall 132a. When the blade assembly 130 is assembled, the sleeved portion 132c is sleeved to one end of the shaft 126 to fasten the shaft 126 to the top wall 132a, and the blade assembly 130 is rotatably mounted to the stator 120. When the blade assembly 130 rotates, airflow is inducted or exhausted through the holes H1. In the embodiment, the blade assembly 130 is a centrifugal blade assembly 130, and the air inducting direction is vertical to the air exhausting direction.

In the embodiment, the motherboard 100 includes a fan control unit 140. The circuit board 110 includes a circuit C disposed at the connecting portion 114. The fan control unit 140 is disposed at the circuit board 110 and is electrically connected with the stator 120 via the circuit C. Besides transmitting control signals, the circuit C also provide power to allow the motherboard 100 to control the stator 120 and to supply the power for the stator 120 without additional signal wires and power wires. In the embodiment, the fan control unit 140 includes a diode 142 and a resistor 144 for rectification and adjusting working voltages.

In addition, the motherboard 100 further includes a Hall element 160. The Hall element 160 is a sensing device and sense changes in a magnetic field to output different voltages. In the embodiment, the Hall element 160 is disposed at the supporting area 112 and is located below the magnets 136 for sensing the changes in the magnetic field when the magnets 136 rotates with the hub casing 132, thus to obtain the voltage corresponding to the rotating speed of the hub casing 132. The Hall element 160 is electrically connected with the fan control unit 140 via the circuit board 110 thus to transmit the voltage to a controller 146 in a plurality of the fan control units 140. The controller 146 controls the stator 120 according to the voltage.

In the embodiment, the motherboard 100 further has a central processing unit (CPU) connector CS, a chipset 116, a memory module connector MS, and an input/output device I. The CPU connector CS, the chipset 116, and the memory module connector MS are disposed at the circuit board 110. The CPU connector CS, the memory module connector MS, and the input/output device I are electrically connected with the chipset 116. The CPU connector CS is used for connecting a CPU (not shown), the memory module connector MS is used for connecting a memory module (not shown), and the chipset 116 is connected with the CPU connector CS, the memory module connector MS, and the input/output device I. The common input/output device I may be a memory card slot, an external serial advanced technology attachment (eSATA) socket, a universal serial bus (USB) socket, a sound socket, an Ethernet socket and so on.

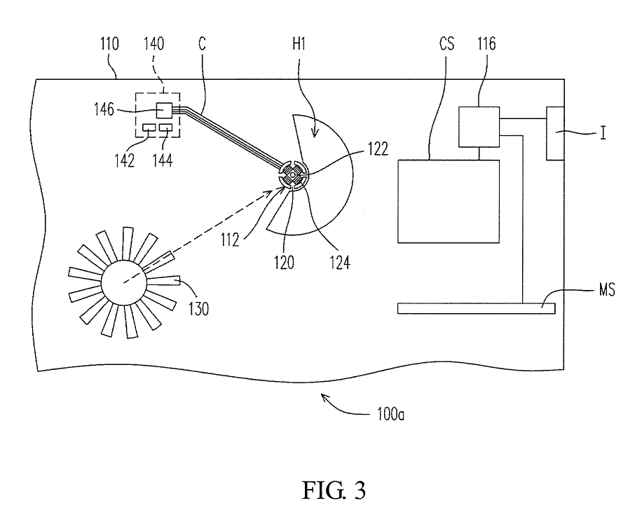

FIG. 3 is a partial schematic diagram showing a motherboard according to another embodiment of the invention. Please refer to FIG. 3. A motherboard 100a in FIG. 3 is substantially the same as the motherboard 100 in FIG, 1. Therefore, the same or similar elements are indicated by the same or the similar reference marks, and they are not described for a concise purpose. The difference between the motherboard 100 and the motherboard 100a is that a circuit board 110a only has a hole H1 adjacent to a supporting area 112 and the supporting area 112 is connected with the circuit board 110a via a connecting portion 114.

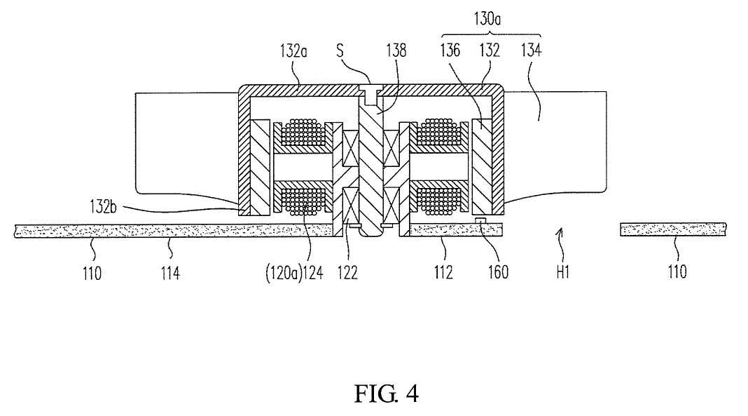

FIG. 4 is a sectional schematic diagram showing a blade assembly, a stator, and a part of the motherboard according to another embodiment of the invention. Please refer to FIG. 4. A stator 120a and a blade assembly 130a in the embodiment are substantially the same as the stator 120 and the blade assembly 130 in FIG. 2. Therefore, the same or the similar elements are indicated by the same or similar reference marks, and they are not described for a concise purpose. The difference is described hereinbelow.

The stator 120a includes a plurality of stator coils 124, and the stator coils 124 are disposed around a bearing 122. The blade assembly 130a includes a hub casing 132, a plurality of blades 134, a plurality of magnets 136, and a shaft 138. One end of the shaft 138 is fastened to a top wall 132a. For example, a locking element S may be used to fasten the shaft 138 to the top wall 132a. Then, the other end of the shaft 138 is sleeved in the bearing 122. Thereby, the blade assembly 130a is mounted to the stator 120a.

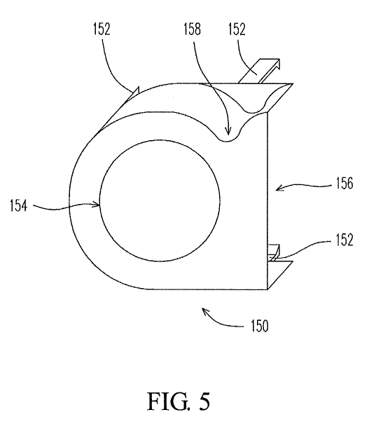

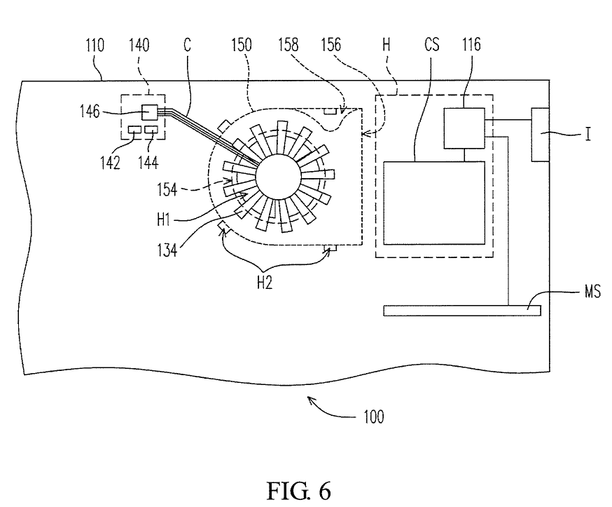

FIG. 5 is a schematic diagram showing a guiding casing according to one embodiment of the invention. FIG. 6 is a schematic diagram showing the guiding casing in FIG. 5 fastened to the motherboard in FIG. 1. Please refer to FIG. 5 and FIG. 6. In FIG. 6, to show objects covered by the guiding casing 150, the position of the guiding casing 150 assembled at the circuit board 110 is shown by dotted lines. In the embodiment, the motherboard 100 further includes a guiding casing 150 fastened to the circuit board 110 and covering the blade assembly 130. The guiding casing 150 have a plurality of fastening elements 152. Further, a plurality of fastening holes H2 are disposed at the corresponding positions of the circuit board 110. The fastening elements 152 are fastened in the fastening holes H2 to fasten the guiding casing 150 to the circuit board 110.

A passage is formed between the guiding casing 150 and the circuit board 110, and an air outlet 156 of the guiding casing 150 faces a heating area H. A chipset 116 and a central processing unit (CPU) connector CS are located in the heating area H. When the chipset 116 and a central processing unit (not shown) assembled at the central processing unit connector CS run, they may generate a large amount of heat. The airflow driven by the blade assembly 130 can be guided to the heating area H to forcedly dissipate the heat, thereby improving the heat dissipating efficiency. A heat dissipating fin is assembled at chips, such as the central processing unit, generating a large mount of heat, and the airflow forcedly dissipate the heat to further increase the heat dissipating efficiency.

In addition, the guiding casing 150 further have an air inlet 154 corresponding to the blade assembly 130. The blade assembly 130 inducts air via the air inlet 154 and the hole H1 at the circuit board 110 at the same time. Thus, the blade assembly 130 sends enough air via the smaller blades 134, thereby reducing the whole height of the motherboard 100.

In addition, the shape of the guiding casing 150 may be changed according to the heat distribution condition of the heating area H, thereby sending more airflow to areas with greater heat. In the embodiment, the guiding casing 150 has a contracted portion 158. After the airflow passes through the contracted portion 158, the pressure of the airflow at the air outlet 156 presents an uneven distribution. The pressure of one portion is higher to allow the area with greater heat to obtain enough airflow.

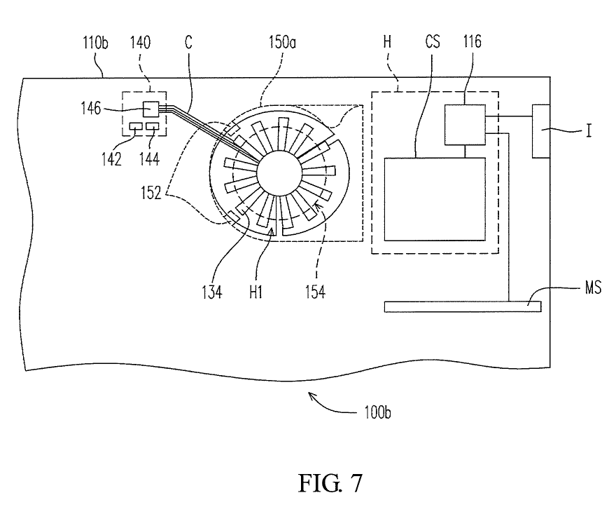

FIG. 7 is a sectional schematic diagram showing a guiding casing fastened to a motherboard according to another embodiment of the invention. Please refer to FIG. 7. A motherboard 100b is substantially the same as the motherboard 100 in FIG. 1. Therefore, the same or similar elements are indicated by the same or similar reference marks, and they are not described for a concise purpose. In the embodiment, an edge of a hole H1 of the circuit board 110b is adjacent to a fastening element 152. Therefore, the fastening element 152 can be fastened to the edge of the hole H1, and the guiding casing 150 can be fastened to the circuit board 110b without additional fastening holes at the circuit board 110b.

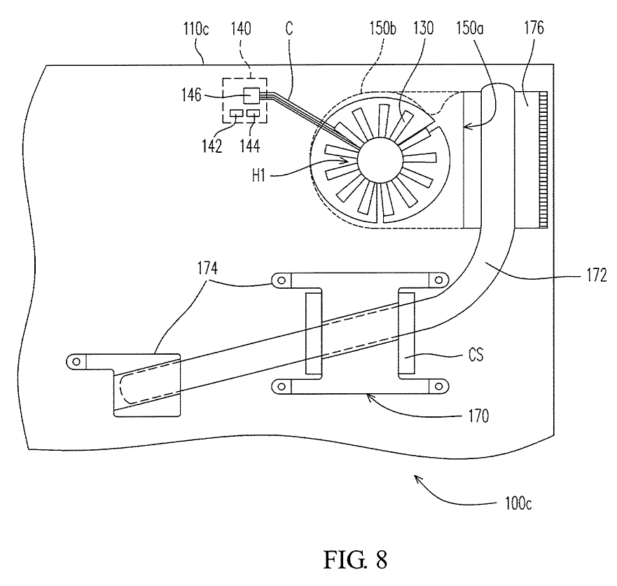

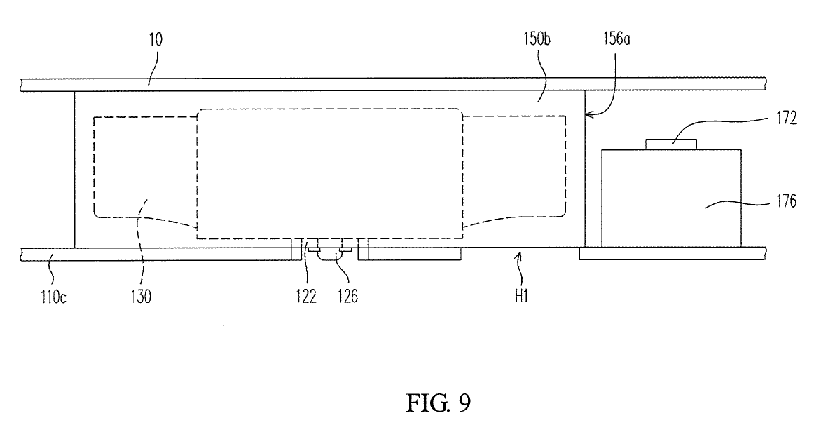

FIG. 8 is a partial schematic diagram showing a motherboard according to a third embodiment of the invention. FIG. 9 is a side schematic diagram showing the motherboard in FIG. 8 and a casing assembled at the motherboard. Please refer to FIG. 8 and FIG. 9 together. A motherboard 100c is substantially the same as the motherboard 100 in FIG. 1. Therefore, the same or similar elements are indicated by the same or similar reference marks, and they are not described for a concise purpose.

In the embodiment, a guiding casing 150b is fastened to a casing 10. The casing 10 is located above a circuit board 110c, and the assembled position of the guiding casing 150b corresponds to that of the blade assembly 130. When the casing 10 is assembled to the motherboard 100c, the guiding casing 150b covers the blade assembly 130. Please refer to FIG. 8, The guiding casing 150b is shown in dotted lines.

In the embodiment, the motherboard 100c further includes a heat pipe module 170. The heat pipe module 170 includes a heat pipe 172, a plurality of chip pads 174, and a heat dissipating fin 176. The heat dissipating fin 176 is adjacent to an air outlet 156a of the guiding casing 150b. The positions of the chip pads 174 correspond to that of a chipset (not shown) and a central processing unit connector CS. The heat pipe 172 connects each of the chip pads 174 and the heat dissipating fin 176. Each of the chip pads 174 is fastened to the circuit board 110c. The heat generated by the chipset and the central processing unit is guided to the heat dissipating fin 176 via the heat pipe 172. The guiding casing 150b guides the airflow from the blade assembly 130 to the heat dissipating fin 176 thus to dissipate the heat, thereby cooling the chipset and the CPU.

To sum up, according to the motherboard in the embodiments of the invention, part components of the fan are integrated to the motherboard. The hole of the motherboard may be used as the air inlet of the fan, and the fan does not need other air inlet. The circuit of the motherboard is used to supply power and transmit signals, and there is no need to dispose connectors and power wires. Thus, the component cost will be saved, and volume spaced by the components will be reduced, thereby reducing the height of the motherboard. In addition, the guiding casing may be disposed at the motherboard. Thus, the airflow driven by the blade assembly will be centralized in the heating area to improve the heat dissipating efficiency.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A motherboard integrated with a fan, comprising:
a circuit board having at least one hole;
a stator disposed at the circuit board; and
a blade assembly rotatably mounted to the stator,
wherein when the stator drives the blade assembly to rotate, airflow is formed and passes through the hole.

2. The motherboard according to claim 1, further comprising a fan control unit disposed at the circuit board and electrically connected with the stator.

3. The motherboard according to claim 2, wherein the fan control unit comprises a diode and a resistor.

4. The motherboard according to claim 2, wherein the circuit board comprises a circuit electrically connected with the stator and the fan control unit.

5. The motherboard according to claim 1, further comprising a bearing, the stator including a plurality of stator coils disposed around the bearing.

6. The motherboard according to claim 5, further comprising a shaft sleeved in the bearing.

7. The motherboard according to claim 6, wherein the blade assembly comprises a hub casing, a plurality of blades, and a plurality of magnets, the hub casing covers the stator and is assembled at the shaft, the blades are connected to the outside of the hub casing, and the magnets are disposed in the hub casing and correspond to the stator coils.

8. The motherboard according to claim 7, further comprising a Hall element and a fan control unit, the fan control unit disposed at the circuit board and electrically connected with the stator, the Hall element disposed at the circuit board and electrically connected with the fan control unit for sensing position changes of the magnets thus to transmit a voltage corresponding to a rotating speed of the blade assembly to the fan control unit.

9. The motherboard according to claim 1, wherein the circuit board comprises at least one connecting portion adjacent to the hole.

10. The motherboard according to claim 1, wherein the blade assembly is a centrifugal blade assembly.

11. The motherboard according to claim 1, further comprising a guiding casing fastened to the circuit board and covering the blade assembly.

12. The motherboard according to claim 11, wherein the guiding casing has a plurality of fastening elements fastened to the circuit board.

13. The motherboard according to claim 11, wherein the guiding casing has a plurality of fastening elements fastened to a casing.

14. The motherboard according to claim 11, wherein the guiding casing has an air inlet corresponding to the blade assembly.

15. The motherboard according to claim 1, further comprising a central processing unit connector, a chipset, and a memory module connector, the central processing unit connector, the chipset, and the memory module connector disposed at the circuit board, the central processing unit connector and the memory module connector electrically connected with the chipset.

16. The motherboard according to claim 15, further comprising at least one input/output device electrically connected with the chipset.
